(19) United States
(12) Patent Application Publication
(10) Pub. No.: US 2025/0183163 A1
(43) Pub. Date: Jun. 5, 2025

(54) SEMICONDUCTOR PACKAGE

(71) Applicant: Samsung Electronics Co., Ltd., Suwon-si (KR)

(72) Inventors: Juyoun Choi, Suwon-si (KR); Eunkyeong Park, Suwon-si (KR); Kyeongsik Jang, Suwon-si (KR)

(21) Appl. No.: 18/794,299

(22) Filed: Aug. 5, 2024

(30) Foreign Application Priority Data
Dec. 1, 2023 (KR) 10-2023-0172729

(51) Int. Cl. H01L 23/522; H01L 23/00; H01L 23/14; H01L 23/498; H01L 23/538; H01L 25/18; H10B 80/00

(52) U.S. Cl. CPC H01L 23/5227; H01L 23/145; H01L 23/49833; H01L 23/49838; H01L 23/5223; H01L 23/5386; H01L 24/16; H01L 24/32; H01L 24/73; H01L 25/18; H01L 2224/16225; H01L 2224/32225; H01L 2224/73204; H01L 2924/1431; H01L 2924/1436; H01L 2924/19041; H10B 80/00

(57) ABSTRACT

A semiconductor package includes a package substrate, an organic interposer above the package substrate and electrically connected to the package substrate, the organic interposer including an inductor, a capacitor, and a bridge chip, and a plurality of semiconductor chips above the organic interposer and electrically connected to the organic interposer, wherein the plurality of semiconductor chips includes a power management semiconductor chip, the power management semiconductor chip being above and adjacent to the inductor and the capacitor, and at least some of the plurality of semiconductor chips being electrically connected to each other by the bridge chip.

### CROSS-REFERENCE TO RELATED APPLICATION

This application is based on and claims priority under 35 U.S.C. § 119 to Korean Patent Application No. 10-2023-0172729, filed on Dec. 1, 2023, in the Korean Intellectual Property Office, the disclosure of which is incorporated by reference herein in its entirety.

### BACKGROUND

The inventive concept relates to a semiconductor package, and more particularly, to a semiconductor package including semiconductor chips, an inductor, and a capacitor.

Semiconductor packages may include a plurality of semiconductor chips, an inductor, and a capacitor, which are all mounted on a package substrate. With the miniaturization of electronic equipment and the increasing integration density of electronic devices, semiconductor packages are becoming more compact and systemized. Therefore, it is important to reduce the mounting areas of semiconductor chips, an inductor, and a capacitor in semiconductor packages while improving the electrical characteristics thereof.

### SUMMARY

The inventive concept provides a semiconductor package with a reduced area of a surface of a package substrate, on which semiconductor chips, an inductor, and a capacitor are mounted, and improved electrical characteristics.

According to an aspect of the inventive concept, a semiconductor package includes a package substrate; an organic interposer above the package substrate and electrically connected to the package substrate, the organic interposer including an inductor, a capacitor, and a bridge chip; and a plurality of semiconductor chips above the organic interposer and electrically connected to the organic interposer, wherein the plurality of semiconductor chips includes a power management semiconductor chip, wherein the power management semiconductor chip is above and adjacent to the inductor and the capacitor, and wherein at least some of the plurality of semiconductor chips are electrically connected to each other by the bridge chip.

According to another aspect of the inventive concept, a semiconductor package includes a package substrate; an organic interposer above the package substrate and electrically connected to the package substrate, the organic interposer including an organic body, a post electrode penetrating the organic body from a top of the organic body to a bottom of the organic body, a lower redistribution structure arranged below the organic body and electrically connected to the post electrode, and an upper redistribution structure arranged above the organic body and electrically connected to the post electrode, an inductor in at least one of the upper redistribution structure and the lower redistribution structure, a capacitor inside the organic body, and a bridge chip inside the organic body; and a plurality of semiconductor chips above the organic interposer and electrically connected to the organic interposer, wherein the plurality of semiconductor chips includes a power management semiconductor chip, wherein the power management semiconductor chip is above and adjacent to the inductor and the capacitor, and wherein at least some of the plurality of semiconductor chips are electrically connected to each other by the bridge chip.

According to a further aspect of the inventive concept, a semiconductor package includes a package substrate; an organic interposer above the package substrate and electrically connected to the package substrate through a first internal connection terminal, the organic interposer including an organic body, a plurality of post electrodes penetrating the organic body from a top of the organic body to a bottom of the organic body, a lower redistribution structure arranged below the organic body and electrically connected to the plurality of post electrodes, and an upper redistribution structure arranged above the organic body and electrically connected to the plurality of post electrodes, an inductor in at least one of the lower redistribution structure and the upper redistribution structure, a capacitor embedded in the organic body, and a bridge chip embedded in the organic body, the plurality of post electrodes including a plurality of first post electrodes electrically connected to the inductor and a plurality of second post electrodes electrically connected to the lower redistribution structure and the upper redistribution structure; and a plurality of semiconductor chips above the organic interposer and electrically connected to the organic interposer through a second internal connection terminal, wherein the plurality of semiconductor chips includes a power management semiconductor chip, wherein the power management semiconductor chip is above and adjacent to the inductor and the capacitor, wherein at least some of the plurality of semiconductor chips are electrically connected to each other by the bridge chip, and wherein the plurality of semiconductor chips includes at least one of a logic chip and a memory chip.

### BRIEF DESCRIPTION OF THE DRAWINGS

Embodiments will be more clearly understood from the following detailed description taken in conjunction with the accompanying drawings in which:

FIG. 1 is a cross-sectional view of a main part of a semiconductor package according to an embodiment;

FIG. 2 is a partial enlarged view of FIG. 1;

FIGS. 3 to 5 are diagrams illustrating an inductor of FIG. 1;

FIG. 6 is a cross-sectional view illustrating a lower redistribution structure forming an organic interposer of a semiconductor package, according to an embodiment;

FIG. 7 is a cross-sectional view illustrating an upper redistribution structure forming an organic interposer of a semiconductor package, according to an embodiment;

FIGS. 8 and 9 are top views of an organic body forming an organic interposer of a semiconductor package, according to an embodiment;

FIGS. 10 and 11 are bottom views of an organic body forming an organic interposer of a semiconductor package, according to an embodiment;

FIG. 12 is a top view of an organic body forming an organic interposer of a semiconductor package, according to an embodiment;

FIG. 13 is a bottom view of an organic body forming an organic interposer of a semiconductor package, according to an embodiment;

FIG. 14 is a cross-sectional view illustrating an organic interposer of a semiconductor package, according to an embodiment;

FIG. 15 is a cross-sectional view of a main part of a semiconductor package according to an embodiment;

FIG. 16 is a block diagram of a semiconductor package according to an embodiment; and

FIG. 17 is a schematic block diagram of a semiconductor package according to an embodiment.

### DETAILED DESCRIPTION OF THE EMBODIMENTS

Hereinafter, embodiments are described in detail with reference to the accompanying drawings. In the drawing, like reference characters or numerals denote like elements, and redundant descriptions thereof will be brief or omitted.

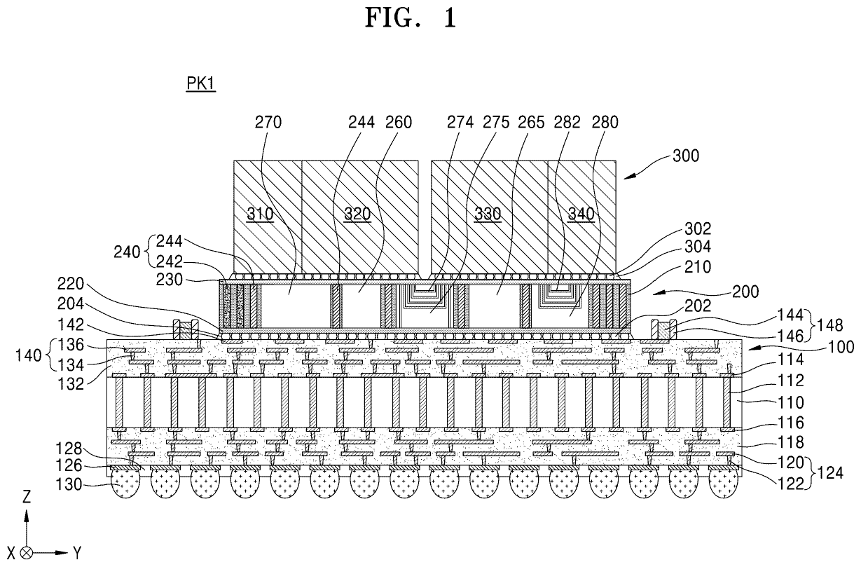

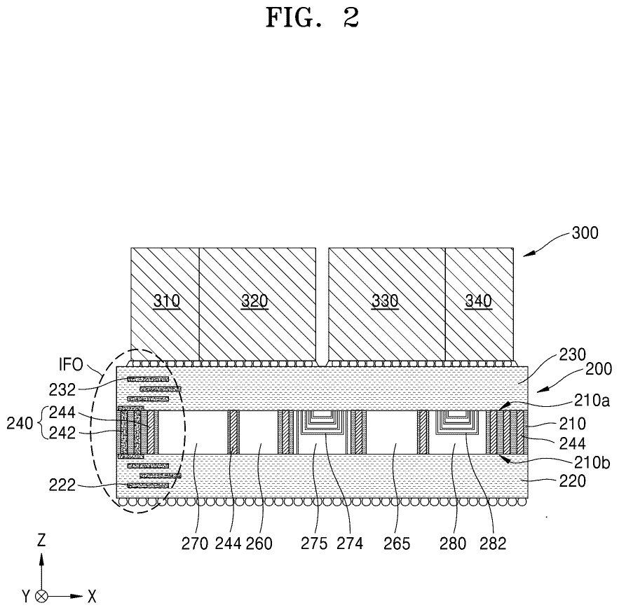

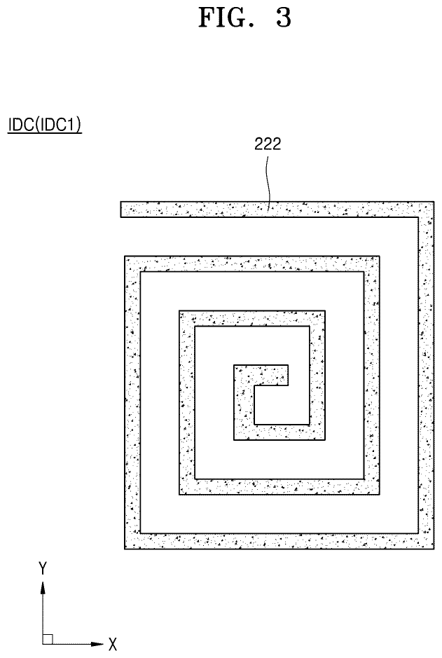

FIG. 1 is a cross-sectional view of a main part of a semiconductor package according to an embodiment. FIG. 2 is a partial enlarged view of FIG. 1. FIGS. 3 to 5 are diagrams illustrating an inductor of FIG. 1.

A semiconductor package PK1 may include a package substrate 100, an organic interposer 200, and a semiconductor chip group 300. In some embodiments, the package substrate 100 may include a printed circuit board (PCB). In some embodiments, the package substrate 100 may include a flexible PCB.

The package substrate 100 may include a core layer 110, core through electrodes 112, first pads 114, and second pads 116. In some embodiments, the core layer 110 may be formed of or include resin or glass fiber. The resin may include phenol resin, epoxy resin, or polyimide.

In some embodiments, the core layer 110 may include at least one material selected from the group consisting of flame retardant 4 (FR4), tetrafunctional epoxy, polyphenylene ether, epoxy/polyphenylene oxide, bismaleimide triazine (BT), thermount, cyanate ester, polyimide, prepreg, Ajinomoto build-up film (ABF), and liquid crystal polymer.

The core through electrodes 112 may penetrate through the core layer 110 in the vertical direction. The vertical direction may refer to a direction that is substantially perpendicular to the top surface of the package substrate 100 and a horizontal direction may refer to a direction that is parallel with the top surface of the package substrate 100.

In some embodiments, the core through electrodes 112 may each have a cylindrical shape. The core through electrodes 112 may extend in the vertical direction. The core through electrodes 112 may extend from the top to the bottom of the core layer 110. The core through electrodes 112 may have the same or different diameters.

In some embodiments, the diameter of the core through electrodes 112 may be about several tens of μm to about several hundreds of μm. In some embodiments, the diameter of the core through electrodes 112 may be about 75 μm to about 190 μm. The core through electrodes 112 may be formed of or include a conductive material.

The core through electrodes 112 may include at least one selected from copper (Cu), aluminum (Al), nickel (Ni), silver (Ag), gold (Au), platinum (Pt), tin (Sn), lead (Pb), titanium (Ti), chrome (Cr), palladium (Pd), indium (In), zinc (Zn), carbon (C), and graphene or an alloy thereof.

The first pads 114 may be deposited on the top surface of the core layer 110 and the second pads 116 may be deposited on the bottom surface of the core layer 110. The first pads 114 may be on the top surfaces of the core through electrodes 112 and the second pads 116 may be on the bottom surfaces of the core through electrodes 112. In some embodiments, the first pads 114 and the second pads 116 may have different widths. The first pads 114 and the second pads 116 may be formed of or include one of the materials mentioned above in relation to the core through electrodes 112.

The package substrate 100 may include a lower insulating layer 118, a lower pad protective layer 128, a lower wiring structure 124, lower connection pads 126, and external connection terminals 130. The lower wiring structure 124 may be referred to as a substrate lower wiring structure. The lower insulating layer 118 may be disposed on the bottom surface of the core layer 110. For example, the lower insulating layer 118 may be formed of or include a dielectric material such as prepreg.

The lower wiring structure 124 may be arranged inside the lower insulating layer 118. The lower wiring structure 124 may include lower wiring layers 120 and lower vias 122. The lower wiring structure 124 may include a substrate lower redistribution structure that rewires the core through electrodes 112 of the core layer 110. The lower wiring structure 124 may be connected to the second pads 116 and the lower connection pads 126.

The lower wiring structure 124 may be embedded in the lower insulating layer 118. The lower wiring layers 120 may extend in the horizontal direction. The lower vias 122 may extend in the vertical direction. The lower wiring structure 124 may be formed of or include a conductive material. The lower wiring structure 124 may provide an electrical path for delivering signals and power.

The lower pad protective layer 128 may be below the lower insulating layer 118. The lower pad protective layer 128 may include an insulating coating film. For example, the lower pad protective layer 128 may be formed of or include solder resist. The lower pad protective layer 128 may protect the lower connection pads 126 and prevent a bridge from occurring between the lower connection pads 126.

The lower connection pads 126 may be arranged on the lower insulating layer 118 and apart from each other in the horizontal direction. The lower connection pads 126 may each have a polygonal shape, such as a quadrangular shape or a hexagonal shape, in a plan view. The lower connection pads 126 may each have a circular shape or an oval shape in a plan view.

In some embodiments, the lower connection pads 126 may have a uniform thickness. The lower connection pads 126 may each have a top surface in contact with the lower insulating layer 118 and/or one of the lower vias 122 and a bottom surface opposite to the top surface. The top and bottom surfaces of the lower connection pads 126 may be flat. The descriptions of the shape and arrangement of the lower connection pads 126 may be similarly applied to other pads, e.g., upper connection pads 142, the first pads 114, and the second pads 116.

The external connection terminals 130 may be respectively deposited on the lower connection pads 126 to electrically connect the semiconductor package PK1 to an external device. For example, the external connection terminals 130 may be formed of or include a solder material. The size of the external connection terminals 130 may be greater than the size of first and second internal connection terminals 202 and 302 described below.

The package substrate 100 may include an upper insulating layer 132, an upper wiring structure 140, and the upper connection pads 142. The upper wiring structure 140 may be referred to as a substrate upper wiring structure. The upper insulating layer 132 may be disposed on the top surface of the core layer 110. For example, the upper insulating layer 132 may be formed of or include a dielectric material such as prepreg.

The upper wiring structure 140 may include upper wiring layers 136 and upper vias 134. The upper wiring structure 140 may include a substrate lower redistribution structure that rewires the core through electrodes 112 of the core layer 110. The upper wiring structure 140 may be arranged inside the upper insulating layer 132.

The upper wiring structure 140 may be connected to the first pads 114 and the upper connection pads 142. The upper wiring structure 140 may be embedded in the upper insulating layer 132. The upper wiring layers 136 may extend in the horizontal direction. The upper vias 134 may extend in the vertical direction. The upper wiring structure 140 may be formed of or include a conductive material. The upper wiring structure 140 may provide an electrical path for delivering signals and power.

The organic interposer 200 may be connected to the package substrate 100 through the first internal connection terminals 202. In some embodiments, a substrate inductor 148 may be on the package substrate 100. The substrate inductor 148 may include a main inductor 144 and a power terminal 146. The substrate inductor 148 may not be formed in some occasions.

The organic interposer 200 may be on the package substrate 100. The organic interposer 200 may electrically connect semiconductor chips (e.g., 310, 320, 330, and 340) to each other. The organic interposer 200 may electrically connect the semiconductor chips (310, 320, 330, and 340) to the package substrate 100. The organic interposer 200 may resolve the mismatch between the footprint of the package substrate 100 and the footprint of the semiconductor chip group 300.

For example, chip pads of the semiconductor chips (310, 320, 330, and 340) forming the semiconductor chip group 300 may be smaller than the upper connection pads 142 of the package substrate 100. The organic interposer 200 between the semiconductor chips (310, 320, 330, and 340) and the package substrate 100 may mediate the connection therebetween.

A first insulating filler 204 may be between the package substrate 100 and the organic interposer 200. The first insulating filler 204 may be formed of or include an epoxy molding compound (EMC) or a non-conductive film (NCF). The first insulating filler 204 may cover the upper connection pads 142 and the first internal connection terminals 202. The first insulating filler 204 may protect the upper connection pads 142 and the first internal connection terminals 202.

The semiconductor chip group 300 may be connected to the organic interposer 200 through the second internal connection terminals 302. The semiconductor chip group 300 may include a power management semiconductor chip 310 (e.g, a voltage regulator chip) and general semiconductor chips 320, 330, and 340 such as logic chips and/or memory chips.

A second insulating filler 304 may be between the organic interposer 200 and the semiconductor chip group 300. The second insulating filler 304 may include an EMC or an NCF. The second insulating filler 304 may be on an upper redistribution structure 230 and may cover the second internal connection terminals 302. The second insulating filler 304 may protect the second internal connection terminals 302.

The organic interposer 200 is described in detail with reference to FIGS. 1 to 5 below.

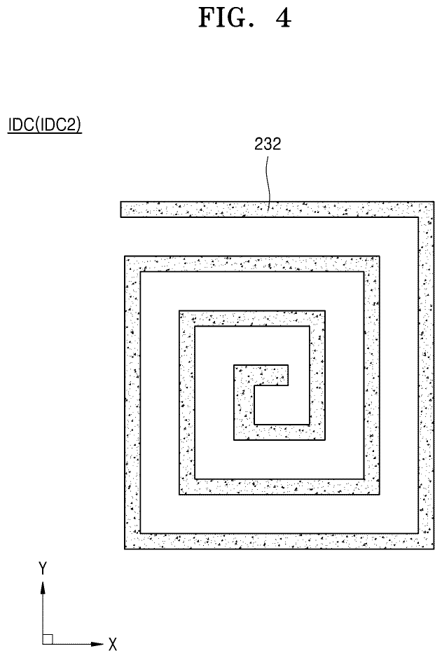

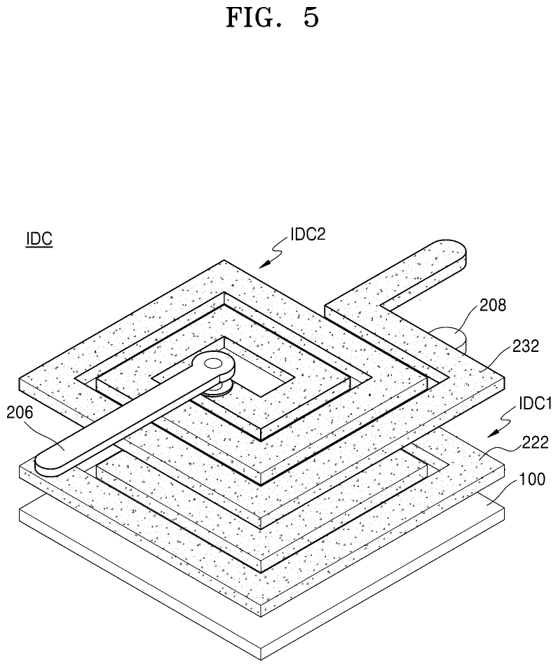

An inductor IDC of FIG. 3 is a plan view of a lower inductor IDC1 including a lower spiral redistribution pattern 222. An inductor IDC of FIG. 4 is a plan view of an upper inductor IDC2 including an upper spiral redistribution pattern 232. An inductor IDC of FIG. 5 is a perspective view illustrating the lower inductor IDC1 including the lower spiral redistribution pattern 222 and the upper inductor IDC2 including the upper spiral redistribution pattern 232.

The organic interposer 200 may be referred to as a molded interposer. The organic interposer 200 may include an organic body 210, a post electrode 240, a lower redistribution structure 220, the upper redistribution structure 230, an inductor (IDC in FIGS. 3 to 5), capacitors (e.g., 260, 265, and 270), and bridge chips (e.g., 275 and 280). Elements of the organic interposer 200 may be embedded in the organic interposer 200, thereby reducing the area of the package substrate 100.

In some embodiments, the capacitors (260, 265, and 270) may include a silicon capacitor or a multi-layer ceramic capacitor (MLCC). The capacitors may include a power management capacitor 270 and chip capacitors 260 and 265. The bridge chips (275 and 280) may be not active chips but passive chips for electrical connection between the general semiconductor chips 320, 330, and 340.

The organic interposer 200 may include the organic body 210, the post electrode 240 penetrating through the organic body 210 from a top surface 210a of the organic body to a bottom surface 210b of the organic body 210, the lower redistribution structure 220 below the organic body 210 and electrically connected to the post electrode 240, and the upper redistribution structure 230 above the organic body 210 and electrically connected to the post electrode 240.

The organic body 210 may not include silicon. The organic body 210 may include one of the materials mentioned above in relation to the core layer 110, excluding semiconductor materials such as silicon. For example, the organic body 210 may include phenol resin, epoxy resin, or polyimide.

The inductor IDC (in FIGS. 3 to 5) may be arranged in a portion IFO below the power management semiconductor chip 310, as shown in FIG. 2. The power management semiconductor chip 310 may be arranged on the inductor IDC (in FIGS. 3 to 5) and the power management capacitor 270.

The power management semiconductor chip 310 may be arranged near the inductor IDC (in FIGS. 3 to 5) and the power management capacitor 270, thereby reducing a parasitic component, e.g., parasitic inductance or parasitic capacitance, of a power supply line. Accordingly, the power management semiconductor chip 310 may efficiently supply power to the general semiconductor chips 320, 330, and 340.

In some embodiments, the inductor IDC (in FIGS. 3 to 5) may include a spiral redistribution pattern (e.g., 222 and 232 in FIGS. 3 to 5) in at least one of the lower redistribution structure 220 and the upper redistribution structure 230. The spiral redistribution pattern may include the lower spiral redistribution pattern 222 and the upper spiral redistribution pattern 232 (FIGS. 3 to 5).

In some embodiments, the inductor IDC (in FIGS. 3 to 5) may include the lower inductor IDC1 including the lower spiral redistribution pattern 222 and the upper inductor IDC2 including the upper spiral redistribution pattern 232. A lower connection line 208 may be connected to the lower inductor IDC1 and an upper connection line 206 may be connected to the upper inductor IDC2. In some embodiments, the inductor IDC (in FIGS. 3 to 5) may include at least one of the lower inductor IDC1 and the upper inductor IDC2.

In some embodiments, the inductor IDC (in FIGS. 3 to 5) may include a spiral redistribution pattern (222 or 232 in FIGS. 3 to 4), which is located in at least one of the lower redistribution structure 220 and the upper redistribution structure 230, and the post electrode 240 electrically connected to the spiral redistribution pattern (222 or 232 in FIGS. 3 to 4).

The post electrode 240 may penetrate through the organic body 210 in the vertical direction. Here, the vertical direction may be substantially perpendicular to the top surface 210a and the bottom surface 210b of the organic body 210. The post electrode 240 may have a cylindrical shape.

The post electrode 240 may include a first post electrode 242 electrically connected to the inductor IDC (in FIGS. 3 to 5). In some embodiments, the first post electrode 242 may be connected to at least one of the lower spiral redistribution pattern 222 of the lower redistribution structure 220 and the upper spiral redistribution pattern 232 of the upper redistribution structure 230.

The post electrode 240 may include a second post electrode 244 electrically connected to the lower redistribution structure 220 and the upper redistribution structure 230. The second post electrode 244 may be electrically connected to respective redistribution layers (or redistribution patterns) of the lower redistribution structure 220 and the upper redistribution structure 230.

The power management capacitor 270, the chip capacitors 260 and 265, and the bridge chips (275 and 280) may be arranged inside the organic interposer 200. The power management capacitor 270, the chip capacitors 260 and 265, and the bridge chips (275 and 280) may be embedded in the organic interposer 200.

In some embodiments, the power management capacitor 270 may be electrically connected to the power management semiconductor chip 310. In some embodiments, the chip capacitors 260 and 265 may be electrically connected to the general semiconductor chips 320, 330, and 340, such as logic chips or memory chips.

The bridge chips may include a first bridge chip 275 and a second bridge chip 280. The first bridge chip 275 may electrically connect the general semiconductor chips 320 and 330 to each other. The first bridge chip 275 may include a first bridge wiring 274. The first bridge wiring 274 may electrically connect the general semiconductor chips 320 and 330 to each other and connect the general semiconductor chips 320 and 330 to the lower and upper redistribution structures 220 and 230.

The second bridge chip 280 may electrically connect the general semiconductor chips 330 and 340 to each other. The second bridge chip 280 may include a second bridge wiring 282. The second bridge wiring 282 may electrically connect the general semiconductor chips 330 and 340 to each other.

As described above, the semiconductor chip group 300 may include the power management semiconductor chip 310 and the general semiconductor chips 320, 330, and 340. The power management semiconductor chip 310 may supply or control power to the semiconductor package PK1. The power management semiconductor chip 310 may correspond to a power management integrated circuit (PMIC) device.

The general semiconductor chips 320, 330, and 340 may include a logic chip or a memory chip. For example, the general semiconductor chips 320 and 330 may be logic chips and the general semiconductor chip 340 may be a memory chip. The memory chip may include a volatile memory chip and/or a non-volatile memory chip.

For example, the volatile memory chip may include dynamic random access memory (DRAM), static RAM (SRAM), thyristor RAM (TRAM), zero capacitor RAM (ZRAM), or twin transistor RAM (TTRAM). For example, the non-volatile memory chip may include flash memory, magnetic RAM (MRAM), spin-transfer torque MRAM (STT-MRAM), ferroelectric RAM (FRAM), phase-change RAM (PRAM), resistive RAM (RRAM), nanotube RRAM, polymer RAM, insulator resistance change memory, or the like.

The memory chip may include a stacked semiconductor memory chip. The stacked semiconductor memory chip may be implemented based on high bandwidth memory (HBM) or hybrid memory cube (HMC) standards. The logic chip may execute applications, which are supported by the semiconductor package PK1, by using the memory chip.

For example, the logic chip may include at least one selected from the group consisting of a central processing unit (CPU), an application processor (AP), a graphics processing unit (GPU), a neural processing unit (NPU), a tensor processing unit (TPU), a vision processing unit (VPU), an image signal processor (ISP) and a digital signal processor (DSP) and may execute specialized operations.

According to the inventive concept described above, the semiconductor package PK1 may include the organic interposer 200 that is mounted on the package substrate 100 and includes the inductor IDC, the capacitors (260, 265, and 270), and the bridge chips (275 and 280). The semiconductor package PK1 may include the semiconductor chip group 300 on the inductor IDC and the capacitors (260, 265, and 270) of the organic interposer 200. The semiconductor chip group 300 may include the power management semiconductor chip 310 and the general semiconductor chips 320, 330, and 340.

According to the inventive concept, the semiconductor package PK1 may reducing the mounting area of the inductor IDC and the capacitors (260, 265, and 270) by having the inductor IDC and the capacitors (260, 265, and 270) inside the organic interposer 200 and may electrically connect the general semiconductor chips 320, 330, and 340 to each other by using the bridge chips (275 and 280) arranged inside the organic interposer 200.

Furthermore, the semiconductor package PK1 may improve the electrical characteristics thereof by having the power management semiconductor chip 310 above the inductor IDC and the power management capacitor 270 to be adjacent (or close) to the inductor IDC and the power management capacitor 270.

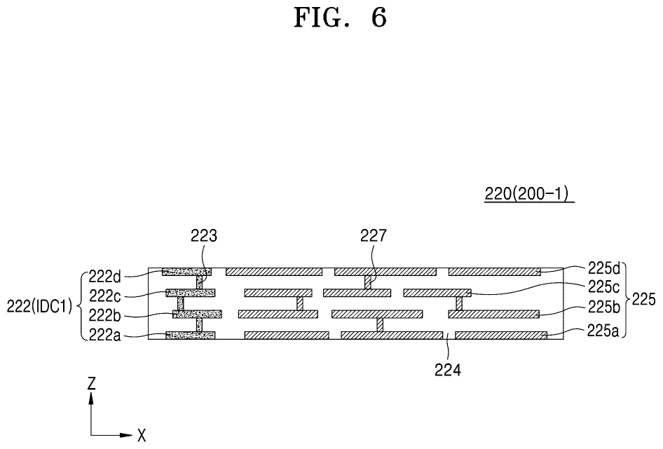

FIG. 6 is a cross-sectional view illustrating a lower redistribution structure included in an organic interposer of a semiconductor package, according to an embodiment.

In detail, an organic interposer 200-1 may include the lower redistribution structure 220. The lower redistribution structure 220 may correspond to the lower redistribution structure 220 in FIGS. 1 and 2.

The lower redistribution structure 220 may include a lower redistribution insulating layer 224, a lower redistribution pattern 225 inside the lower redistribution insulating layer 224, and a first lower redistribution via 227. A plurality of lower redistribution patterns 225 may be arranged inside the lower redistribution insulating layer 224 in the vertical direction (e.g., the Z direction). In some embodiments, the lower redistribution pattern 225 may include a first lower redistribution pattern 225a, a second lower redistribution pattern 225b, a third lower redistribution pattern 225c, and a fourth lower redistribution pattern 225d. The first to fourth lower redistribution patterns 225a, 225b, 225c, and 225d may be electrically connected to each other by the first lower redistribution via 227.

The lower redistribution structure 220 may include the lower spiral redistribution pattern 222, which may constitute the lower inductor IDC1. In some embodiments, the lower spiral redistribution pattern 222 may include a first lower spiral pattern 222a, a second lower spiral pattern 222b, a third lower spiral pattern 222c, and a fourth lower spiral pattern 222d.

The first to fourth lower spiral patterns 222a, 222b, 222c, and 222d may be electrically connected to each other by a second lower redistribution via 223. The first to fourth lower redistribution patterns 225a, 225b, 225c, and 225d may be respectively and electrically connected to the first to fourth lower spiral patterns 222a, 222b, 222c, and 222d. In some embodiments, the first to fourth lower redistribution patterns 225a, 225b, 225c, and 225d may not be electrically connected to the first to fourth lower spiral patterns 222a, 222b, 222c, and 222d.

The first to fourth lower spiral patterns 222a, 222b, 222c, and 222d may form the lower inductor IDC1. Although the lower inductor IDC1 is implemented using four spiral patterns, i.e., the first to fourth lower spiral patterns 222a, 222b, 222c, and 222d in the present embodiment, the lower inductor IDC1 may be implemented using at least one of the first to fourth lower spiral patterns 222a, 222b, 222c, and 222d.

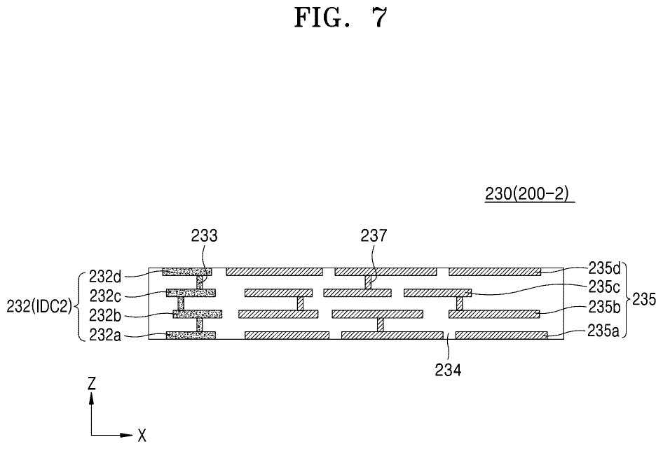

FIG. 7 is a cross-sectional view illustrating an upper redistribution structure forming an organic interposer of a semiconductor package, according to an embodiment.

In detail, an organic interposer 200-2 may include the upper redistribution structure 230. The upper redistribution structure 230 may correspond to the upper redistribution structure 230 in FIGS. 1 and 2.

The upper redistribution structure 230 may include an upper redistribution insulating layer 234, an upper redistribution pattern 235 inside the upper redistribution insulating layer 234, and a first upper redistribution via 237. A plurality of upper redistribution patterns 235 may be arranged inside the upper redistribution insulating layer 234 in the vertical direction (e.g., the Z direction).

In some embodiments, the upper redistribution pattern 235 may include a first upper redistribution pattern 235a, a second upper redistribution pattern 235b, a third upper redistribution pattern 235c, and a fourth upper redistribution pattern 235d. The first to fourth upper redistribution patterns 235a, 235b, 235c, and 235d may be electrically connected to each other by the first upper redistribution via 237.

The upper redistribution structure 230 may include the upper spiral redistribution pattern 232 (in FIG. 3), which may constitute the upper inductor IDC2. In some embodiments, the upper spiral redistribution pattern 232 may include a first upper spiral pattern 232a, a second upper spiral pattern 232b, a third upper spiral pattern 232c, and a fourth upper spiral pattern 232d.

The first to fourth upper spiral patterns 232a, 232b, 232c, and 232d may be electrically connected to each other by a second upper redistribution via 233. The first to fourth upper redistribution patterns 235a, 235b, 235c, and 235d may be respectively and electrically connected to the first to fourth upper spiral patterns 232a, 232b, 232c, and 232d.

The first to fourth upper spiral patterns 232a, 232b, 232c, and 232d may form the upper inductor IDC2. Although the upper inductor IDC2 is implemented using four spiral patterns, i.e., the first to fourth upper spiral patterns 232a, 232b, 232c, and 232d in the present embodiment, the upper inductor IDC2 may be implemented using at least one of the first to fourth upper spiral patterns 232a, 232b, 232c, and 232d.

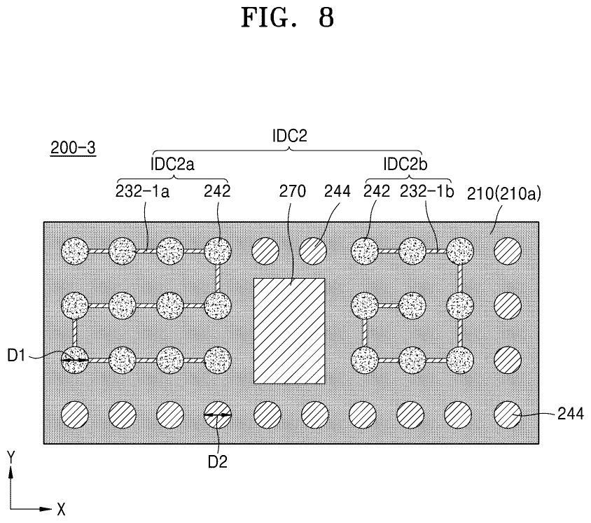

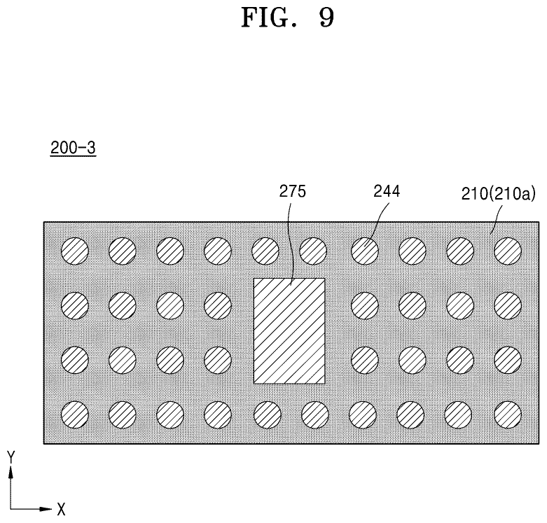

FIGS. 8 and 9 are top views of an organic body forming an organic interposer of a semiconductor package, according to an embodiment.

In detail, FIGS. 8 and 9 may be plan views of the top surface 210a of the organic body 210 in FIG. 2. FIG. 8 is a plan view illustrating the upper inductor IDC2 forming an organic interposer 200-3 and FIG. 9 is a plan view illustrating the organic interposer 200-3 except for the upper inductor IDC2.

Referring to FIGS. 8 and 9, the organic interposer 200-3 may include the organic body 210, the upper inductor IDC2, a post electrode (e.g., 242 and 244), the power management capacitor 270, and the first bridge chip 275.

The post electrode may include a first post electrode 242 electrically connected to the upper inductor IDC2 and a second post electrode 244 electrically connected to the upper redistribution structure 230 (in FIG. 1), e.g., the upper redistribution pattern 235 (in FIG. 7).

The first post electrode 242 may have a first diameter D1. The second post electrode 244 may have a second diameter D2. In some embodiments, the first diameter D1 may be the same as the second diameter D2. In some embodiments, the first diameter D1 and the second diameter D2 may be several tens of μm. In some embodiment, the first diameter D1 and the second diameter D2 may be about 30 μm to about 80 μm.

Referring to FIG. 8, the organic interposer 200-3 may include the upper inductor IDC2 inside the organic body 210. The upper inductor IDC2 may be arranged around the power management capacitor 270. The upper inductor IDC2 may include a first upper inductor IDC2a and a second upper inductor IDC2b respectively at opposite sides of the power management capacitor 270.

The first upper inductor IDC2a may include a first upper spiral pattern 232-1a connecting first post electrodes 242, which are arranged inside the organic body 210, to each other. The second upper inductor IDC2b may include a second upper spiral pattern 232-1b connecting first post electrodes 242, which are arranged inside the organic body 210, to each other.

Referring to FIG. 9, the first bridge chip 275 may be arranged inside the organic body 210. Because an upper spiral pattern is not formed around the first bridge chip 275, an upper inductor may not be provided around the first bridge chip 275. Accordingly, the second post electrode 244, which is electrically connected to the upper redistribution structure 230 (in FIG. 1), e.g., the upper redistribution pattern 235 (in FIG. 7), may be arranged around the first bridge chip 275.

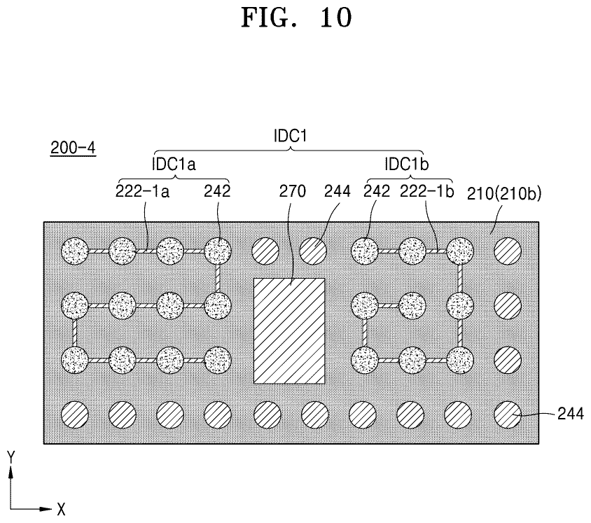

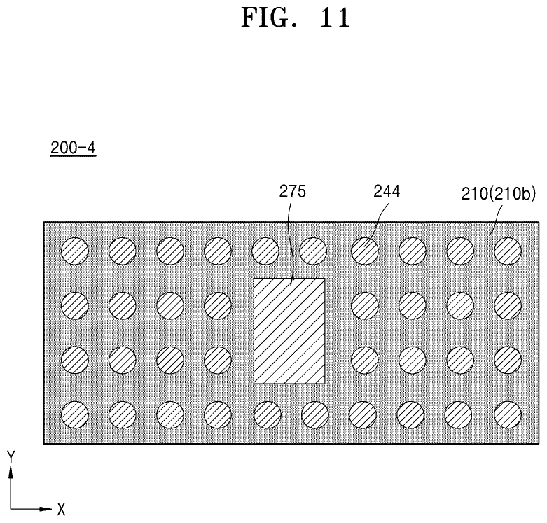

FIGS. 10 and 11 are bottom views of an organic body forming an organic interposer of a semiconductor package, according to an embodiment.

In detail, FIGS. 10 and 11 may be plan views of the bottom surface 210b of the organic body 210 in FIG. 2. FIG. 10 is a plan view illustrating the lower inductor IDC1 included in an organic interposer 200-4 and FIG. 11 is a plan view illustrating the organic interposer 200-4 except for the lower inductor IDC1.

Referring to FIGS. 10 and 11, the organic interposer 200-4 may include the organic body 210, the lower inductor IDC1, a post electrode (e.g., 242 and 244), the power management capacitor 270, and the first bridge chip 275. The post electrode may include a first post electrode 242 electrically connected to the lower inductor IDC1 and a second post electrode 244 electrically connected to the lower redistribution structure 220 (in FIG. 1), e.g., the lower redistribution pattern 225 (in FIG. 6).

Referring to FIG. 10, the organic interposer 200-4 may include the lower inductor IDC1 inside the organic body 210. The lower inductor IDC1 may be arranged around the power management capacitor 270. The lower inductor IDC1 may include a first lower inductor IDC1a and a second lower inductor IDC1b respectively at opposite sides of the power management capacitor 270.

The first lower inductor IDC1a may include a first lower spiral pattern 222-1a connecting first post electrodes 242, which are arranged inside the organic body 210, to each other. The second lower inductor IDC1b may include a second lower spiral pattern 222-1b connecting first post electrodes 242, which are arranged inside the organic body 210, to each other.

Referring to FIG. 11, the first bridge chip 275 may be arranged inside the organic body 210. Because a lower spiral pattern is not formed around the first bridge chip 275, a lower inductor may not be provided around the first bridge chip 275. Accordingly, the second post electrode 244, which is electrically connected to the lower redistribution structure 220 (in FIG. 1), e.g., the lower redistribution pattern 225 (in FIG. 6), may be arranged around the first bridge chip 275.

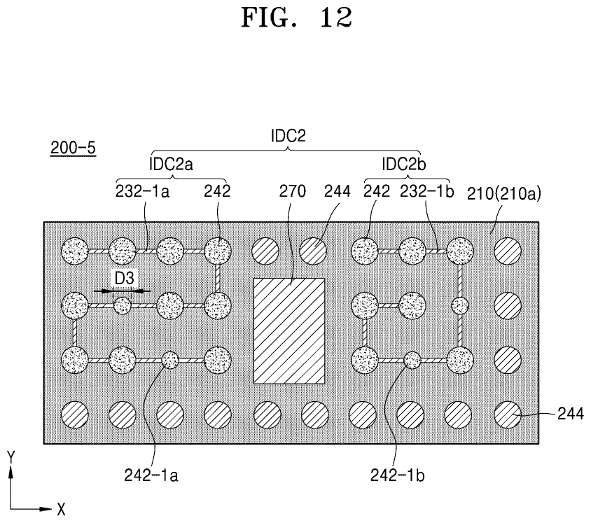

FIG. 12 is a top view of an organic body forming an organic interposer of a semiconductor package, according to an embodiment.

In detail, FIG. 12 may be a plan view of the top surface 210a of the organic body 210 in FIG. 2. An organic interposer 200-5 of FIG. 12 may be the same as the organic interposer 200-3 of FIG. 8, except for first post electrodes 242-1a and 242-1b having a different diameter than the first post electrode 242. In FIGS. 8 and 12, like reference numerals denote like elements.

FIG. 12 is a plan view illustrating the upper inductor IDC2 forming the organic interposer 200-5. Referring to FIG. 12, the organic interposer 200-5 may include the organic body 210, the upper inductor IDC2, a post electrode (e.g., 242, 242-1a, 242-1b, and 244), and the power management capacitor 270.

The post electrode may include first post electrodes 242, 242-1a, 242-1b electrically connected to the upper inductor IDC2 and a second post electrode 244 electrically connected to the upper redistribution structure 230 (in FIG. 1), e.g., the upper redistribution pattern 235 (in FIG. 7). The first post electrode 242 may have the first diameter D1 (in FIG. 8) and the first post electrodes 242-1a and 242-1b may have a third diameter D3.

The second post electrode 244 may have the second diameter D2 (in FIG. 8). In some embodiments, the first diameter D1 may be the same as the second diameter D2 and the third diameter D3 may be less than each of the first diameter D1 and the second diameter D2. In some embodiments, the first diameter D1, the second diameter D2, and the third diameter D3 may be several tens of μm. In some embodiments, the first diameter D1 and the second diameter D2 may be about 60 μm to about 80 μm and the third diameter D3 may be about 30 μm to about 60 μm.

The organic interposer 200-5 may include the upper inductor IDC2 inside the organic body 210. The upper inductor IDC2 may be arranged around the power management capacitor 270. The upper inductor IDC2 may include a first upper inductor IDC2a and a second upper inductor IDC2b respectively at opposite sides of the power management capacitor 270.

The first upper inductor IDC2a may include the first upper spiral pattern 232-1a connecting first post electrodes 242 and 242-1a, which are arranged inside the organic body 210, to each other. The second upper inductor IDC2b may include the second upper spiral pattern 232-1b connecting first post electrodes 242 and 242-1b, which are arranged inside the organic body 210, to each other. As described above, the organic interposer 200-5 may adjust the inductance of the upper inductor IDC2 by adjusting the diameters of the first post electrodes 242, 242-1a, and 242-1b.

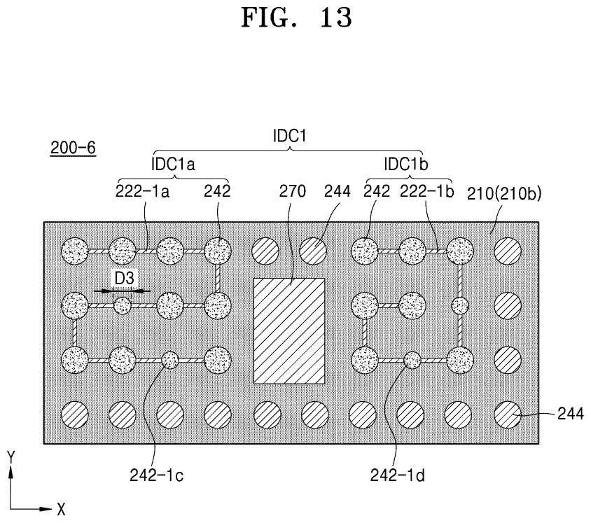

FIG. 13 is a bottom view of an organic body forming an organic interposer of a semiconductor package, according to an embodiment.

In detail, FIG. 13 may be a plan view of the bottom surface 210b of the organic body 210 in FIG. 2. An organic interposer 200-6 of FIG. 13 may be the same as the organic interposer 200-4 of FIG. 10, except for first post electrodes 242-1c and 242-1d having a different diameter than the first post electrode 242. In FIGS. 10 and 13, like reference numerals denote like elements.

FIG. 13 is a plan view illustrating the lower inductor IDC1 forming the organic interposer 200-6. Referring to FIG. 13, the organic interposer 200-6 may include the organic body 210, the lower inductor IDC, a post electrode (e.g., 242, 242-1c, 242-1d, and 244), and the power management capacitor 270.

The post electrode may include first post electrodes 242, 242-1c, and 242-1d electrically connected to the lower inductor IDC and the second post electrode 244 electrically connected to the lower redistribution structure 220 (in FIG. 1), e.g., the lower redistribution pattern 225 (in FIG. 6).

The first post electrode 242 may have the first diameter D1 (in FIG. 8) and the first post electrodes 242-1c and 242-1d may have the third diameter D3. The second post electrode 244 may have the second diameter D2 (in FIG. 8).

In some embodiments, the first diameter D1 may be the same as the second diameter D2 and the third diameter D3 may be less than each of the first diameter D1 and the second diameter D2. In some embodiments, the first diameter D1, the second diameter D2, the third diameter D3 may be several tens of μm. In some embodiments, the first diameter D1 and the second diameter D2 may be about 60 μm to about 80 μm and the third diameter D3 may be about 30 μm to about 60 μm.

The organic interposer 200-6 may include the lower inductor IDC inside the organic body 210. The lower inductor IDC may be arranged around the power management capacitor 270. The lower inductor IDC may include a first lower inductor IDC1a and a second lower inductor IDC1b respectively at opposite sides of the power management capacitor 270.

The first lower inductor IDC1a may include the first lower spiral pattern 222-1a connecting first post electrodes 242 and 242-1c, which are arranged inside the organic body 210, to each other. The second lower inductor IDC1b may include the second lower spiral pattern 222-1b connecting first post electrodes 242 and 242-1d, which are arranged inside the organic body 210, to each other. As described above, the organic interposer 200-6 may adjust the inductance of the lower inductor IDC1 by adjusting the diameters of the first post electrodes 242, 242-1c, and 242-1d.

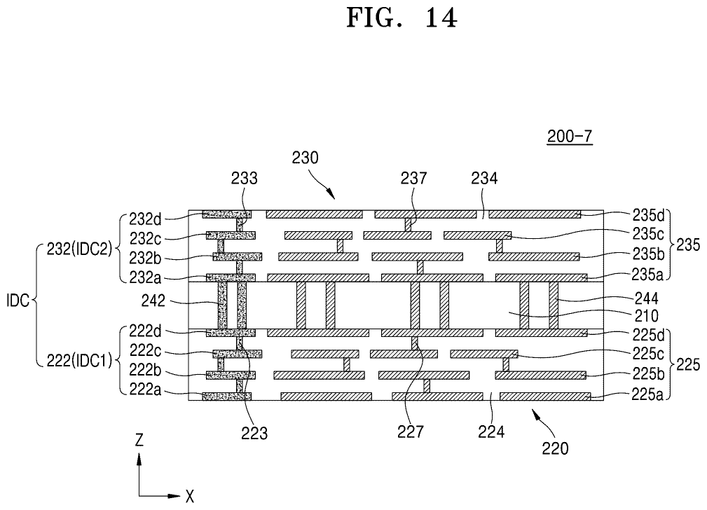

FIG. 14 is a cross-sectional view illustrating an organic interposer of a semiconductor package, according to an embodiment.

In detail, an organic interposer 200-7 may include an organic body 210, a lower redistribution structure 220, an upper redistribution structure 230, a first post electrode 242, and a second post electrode 244.

The first post electrode 242 and the second post electrode 244 may be arranged in the organic body 210. The lower redistribution structure 220 may be below the organic body 210. The lower redistribution structure 220 may correspond to the lower redistribution structure 220 in FIGS. 1 and 2.

The lower redistribution structure 220 may include a lower redistribution pattern 225 and a first lower redistribution via 227 inside the lower redistribution insulating layer 224, as shown in FIG. 6. The lower redistribution pattern 225 may include a first lower redistribution pattern 225a, a second lower redistribution pattern 225b, a third lower redistribution pattern 225c, and a fourth lower redistribution pattern 225d. The first to fourth lower redistribution patterns 225a, 225b, 225c, and 225d may be electrically connected to each other by the first lower redistribution via 227.

The lower redistribution structure 220 may include the lower spiral redistribution pattern 222. The lower spiral redistribution pattern 222 may include a first lower spiral pattern 222a, a second lower spiral pattern 222b, a third lower spiral pattern 222c, and a fourth lower spiral pattern 222d.

The first to fourth lower spiral patterns 222a, 222b, 222c, and 222d may be electrically connected to each other by a second lower redistribution via 223. The first to fourth lower redistribution patterns 225a, 225b, 225c, and 225d may be respectively and electrically connected to the first to fourth lower spiral patterns 222a, 222b, 222c, and 222d. The first to fourth lower spiral patterns 222a, 222b, 222c, and 222d may form the lower inductor IDC1.

The upper redistribution structure 230 may be above the organic body 210. The upper redistribution structure 230 may correspond to the upper redistribution structure 230 in FIGS. 1 and 2. The upper redistribution structure 230 may include an upper redistribution pattern 235 and a first upper redistribution via 237 inside the upper redistribution layer 234.

The upper redistribution pattern 235 may include a first upper redistribution pattern 235a, a second upper redistribution pattern 235b, a third upper redistribution pattern 235c, and a fourth upper redistribution pattern 235d. The first to fourth upper redistribution patterns 235a, 235b, 235c, and 235d may be electrically connected to each other by the first upper redistribution via 237.

The upper redistribution structure 230 may include the upper spiral redistribution pattern 232 (in FIG. 3). The upper spiral redistribution pattern 232 may include a first upper spiral pattern 232a, a second upper spiral pattern 232b, a third upper spiral pattern 232c, and a fourth upper spiral pattern 232d.

The first to fourth upper spiral patterns 232a, 232b, 232c, and 232d may be electrically connected to each other by a second upper redistribution via 233. The first to fourth upper redistribution patterns 235a, 235b, 235c, and 235d may be respectively and electrically connected to the first to fourth upper spiral patterns 232a, 232b, 232c, and 232d. The first to fourth upper spiral patterns 232a, 232b, 232c, and 232d may form the upper inductor IDC2.

The first post electrode 242 may electrically connect the lower spiral redistribution pattern 222 of the lower redistribution structure 220 to the upper spiral redistribution pattern 232 of the upper redistribution structure 230. The second post electrode 244 may electrically connect the lower redistribution pattern 225 of the lower redistribution structure 220 to the upper redistribution pattern 235 of the upper redistribution structure 230. The use of the first post electrode 242 to electrically connect the lower spiral redistribution pattern 222 to the upper spiral redistribution pattern 232 may reduce a DC resistance value of the inductor IDC and/or may enable the reduction of an area of the inductor IDC.

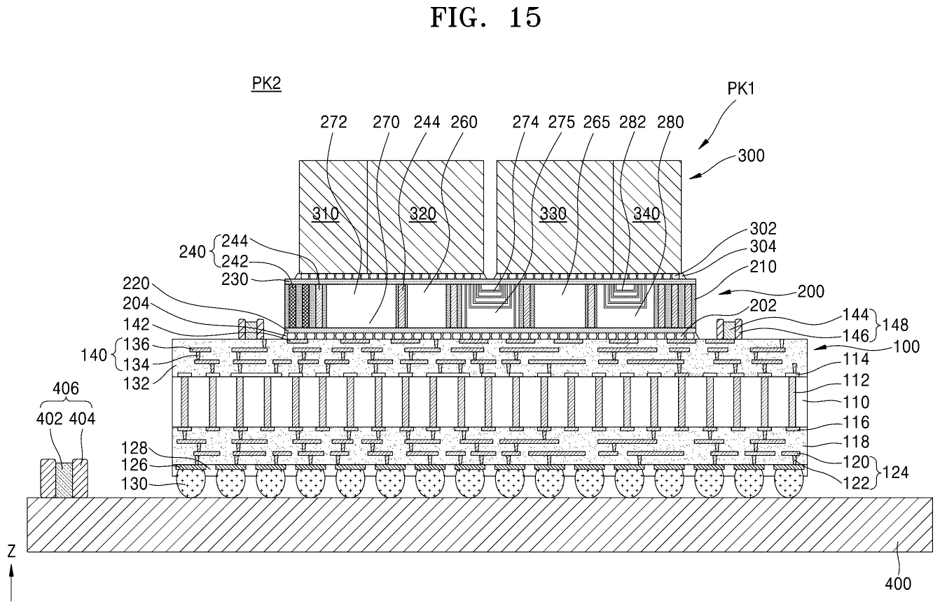

FIG. 15 is a cross-sectional view of a main part of a semiconductor package according to an embodiment.

In detail, a semiconductor package PK2 may include a board substrate 400 and the semiconductor package PK1 mounted on the board substrate 400. The semiconductor package PK1 may include the package substrate 100, the organic interposer 200, and the semiconductor chip group 300, as shown in FIGS. 1 to 5.

The organic interposer 200 may include the organic body 210, the post electrode 240, the lower redistribution structure 220, the inductor IDC (in FIGS. 3 to 5), capacitors (e.g., 260, 265, and 270), and bridge chips (e.g., 274 and 280).

Elements of the organic interposer 200 may be embedded in the organic interposer 200, and accordingly, the area of the package substrate 100 may be reduced. The capacitors may include the power management capacitor 270 and the chip capacitors 260 and 265. The semiconductor package PK1 has been described with reference to FIGS. 1 to 5 above, and thus, detailed descriptions thereof are omitted below.

The board substrate 400 may include a PCB. A board inductor 406 may be mounted on the board substrate 400. The board inductor 406 may be arranged outside the semiconductor package PK1. The board inductor 406 may include a main inductor 402 and a power terminal 404. The board inductor 406 may be omitted in some occasions. Not only the semiconductor package PK1 but also other electronic devices may be mounted on the board substrate 400 to implement various functions.

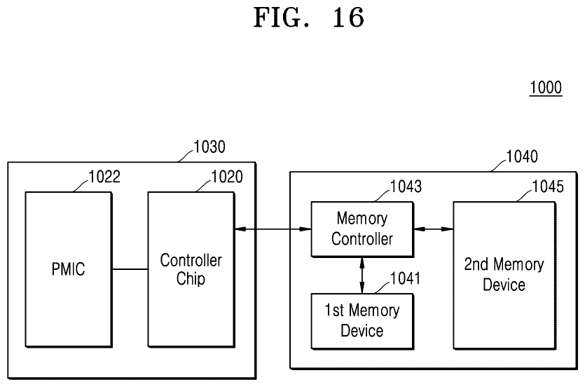

FIG. 16 is a block diagram of a semiconductor package according to an embodiment.

In detail, a semiconductor package 1000 may correspond to the semiconductor package PK1 or PK2. The semiconductor package 1000 may include a first portion 1030 and a second portion 1040. The first portion includes a controller chip 1020 and a PMIC (or a power management semiconductor chip) 1022. The second portion 1040 includes a first memory chip (or device) 1041, a second memory chip (or device) 1045, and a memory controller 1043. The PMIC 1022 supplies the current of an operating voltage to each of the controller chip 1020, the first memory chip 1041, the second memory chip 1045, and the memory controller 1043. Operating voltages respectively applied to the elements may be designed to be the same or different.

The PMIC 1022 may correspond to the power management semiconductor chip 310 described above. The controller chip 1020, the first memory chip 1041, the second memory chip 1045, and the memory controller 1043 may each correspond to the general semiconductor chip 320, 330, or 340.

The semiconductor package 1000 may be configured to be included in a personal computer (PC) or a mobile device. The mobile device may include a laptop computer, a mobile phone, a smartphone, a tablet PC, a personal digital assistant (PDA), an enterprise digital assistant (EDA), a digital still camera, a digital video camera, a portable multimedia player (PMP), a personal navigation device or portable navigation device (PND), a handheld game console, a mobile Internet device (MID), a wearable computer, an Internet of things (IoT) device, an Internet of everything (IoE) device, or a drone.

The controller chip 1020 may control the operation of each of the first memory chip 1041, the second memory chip 1045, and the memory controller 1043.

For example, the controller chip 1020 may include an integrated circuit (IC), a system-on-chip (SoC), an AP, a mobile AP, a chipset, or a set of chips. For example, the controller chip 1020 may include a CPU, a GPU, and/or a modem. In some embodiments, the controller chip 1020 may function as a modem and an AP.

The memory controller 1043 may control the second memory chip 1045 under control by the controller chip 1020. The first memory chip 1041 may include a volatile memory device. The volatile memory device may include, but is not limited to, RAM, DRAM, or SRAM. The second memory chip 1045 may correspond to a storage memory device. The storage memory device may include a non-volatile memory device.

The storage memory device may include, but is not limited to a flash-based memory device. The second memory chip 1045 may correspond to a NAND-type flash memory device. The NAND-type flash memory device may include a two-dimensional (2D) memory cell array or a three-dimensional (3D) memory cell array. The 2D memory cell array or the 3D memory cell array may include a plurality of memory cells. Each of the memory cells may store one bit or at least two bits of information.

When the second memory chip 1045 is a flash-based memory device, the memory controller 1043 may use or support a multimedia card (MMC) interface, an embedded MMC (eMMC) interface, or a universal flash storage (UFS) interface but not limited thereto.

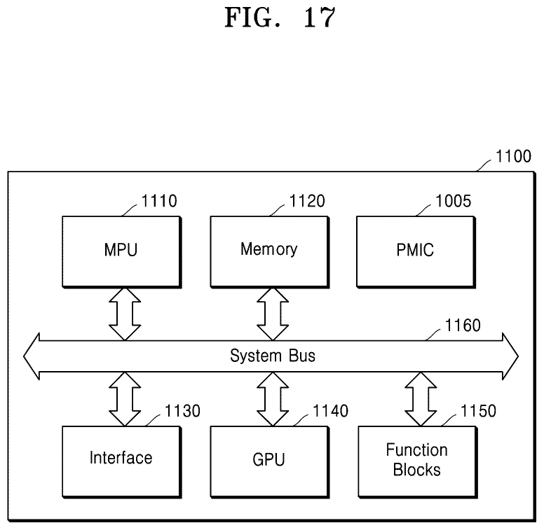

FIG. 17 is a schematic block diagram of a semiconductor package according to an embodiment.

In detail, a semiconductor package 1100 may include a microprocessor unit (MPU) 1110, a memory 1120, an interface 1130, a GPU 1140, function blocks 1150, and a system bus 1160 which connects the MPU 1110, the memory 1120, the interface 1130, the GPU 1140, and the function blocks 1150 to each other. The semiconductor package 1100 may include both the MPU 1110 and the GPU 1140 or only one of the MPU 1110 and the GPU 1140.

The semiconductor package 1100 may further include a PMIC 1005 which supplies the current of an operation voltage to each of the MPU 1110, the memory 1120, the interface 1130, the GPU 1140, and the function blocks 1150. The PMIC 1005 may correspond to the power management semiconductor chip 310 described above.

The MPU 1110 may include a core and an L2 cache. For example, the MPU 1110 may include multiple cores. The multiple cores may have the same or different performance.

The multiple cores may be activated simultaneously or at different times. The memory 1120 may store results of processes performed by the function blocks 1150 under control by the MPU 1110. For example, content stored in the L2 cache of the MPU 1110 may be flushed and thus stored in the memory 1120. The interface 1130 may interface with external devices. For example, the interface 1130 may interface with a camera, a liquid crystal display (LCD), and a speaker.

The GPU 1140 may perform graphics functions. For example, the GPU 1140 may perform video coding or process 3D graphics. The function blocks 1150 may perform various functions. For example, when the semiconductor package 1100 is an AP used in a mobile device, some of the function blocks 1150 may perform a communication function.

The semiconductor package 1100 may correspond to the semiconductor package PK1 or PK2 described above. The MPU 1110, the memory 1120, the interface 1130, the GPU 1140, and the function blocks 1150 may each correspond to the general semiconductor chip 320, 330, or 340. The PMIC 1005 may correspond to the power management semiconductor chip 310.

While the inventive concept has been particularly shown and described with reference to embodiments thereof, it will be understood that various changes in form and details may be made therein without departing from the spirit and scope of the disclosure.

What is claimed is:

1. A semiconductor package comprising:
a package substrate;
an organic interposer above the package substrate and electrically connected to the package substrate, the organic interposer including an inductor, a capacitor, and a bridge chip; and
a plurality of semiconductor chips above the organic interposer and electrically connected to the organic interposer,
wherein the plurality of semiconductor chips includes a power management semiconductor chip,
wherein the power management semiconductor chip is above and adjacent to the inductor and the capacitor, and
wherein at least some of the plurality of semiconductor chips are electrically connected to each other by the bridge chip.

2. The semiconductor package of claim 1, wherein the organic interposer further includes an organic body, a post electrode penetrating the organic body from a top of the organic body to a bottom of the organic body, a lower redistribution structure arranged below the organic body and electrically connected to the post electrode, and an upper redistribution structure arranged above the organic body and electrically connected to the post electrode.

3. The semiconductor package of claim 2, wherein the inductor includes a spiral redistribution pattern located in at least one of the lower redistribution structure and the upper redistribution structure.

4. The semiconductor package of claim 2, wherein the inductor includes a spiral redistribution pattern in at least one of the lower redistribution structure and the upper redistribution structure and the post electrode electrically connected to the spiral redistribution pattern.

5. The semiconductor package of claim 1, wherein the organic interposer comprises a molded interposer.

6. The semiconductor package of claim 1, wherein the organic interposer further includes an organic body and the capacitor is inside the organic body.

7. The semiconductor package of claim 1, wherein the organic interposer further includes an organic body and the bridge chip is inside the organic body.

8. The semiconductor package of claim 1, wherein the plurality of semiconductor chips include at least one of a logic chip and a memory chip.

9. A semiconductor package comprising:
a package substrate;
an organic interposer above the package substrate and electrically connected to the package substrate,
the organic interposer including an organic body, a post electrode penetrating the organic body from a top of the organic body to a bottom of the organic body, a lower redistribution structure arranged below the organic body and electrically connected to the post electrode, and an upper redistribution structure arranged above the organic body and electrically connected to the post electrode,
an inductor in at least one of the upper redistribution structure and the lower redistribution structure, a capacitor inside the organic body, and a bridge chip inside the organic body; and
a plurality of semiconductor chips above the organic interposer and electrically connected to the organic interposer,
wherein the plurality of semiconductor chips includes a power management semiconductor chip,
wherein the power management semiconductor chip is above and adjacent to the inductor and the capacitor, and
wherein at least some of the plurality of semiconductor chips are electrically connected to each other by the bridge chip.

10. The semiconductor package of claim 9, wherein the inductor includes a spiral redistribution pattern in at least one of the lower redistribution structure and the upper redistribution structure.

11. The semiconductor package of claim 9, wherein the inductor includes a spiral redistribution pattern in at least one of the lower redistribution structure and the upper redistribution structure and the post electrode electrically connected to the spiral redistribution pattern.

12. The semiconductor package of claim 9, wherein the capacitor comprises a power management capacitor connected to the power management semiconductor chip.

13. The semiconductor package of claim 12, further comprising a chip capacitor inside the organic body and below the plurality of semiconductor chips, the chip capacitor being connected to the plurality of semiconductor chips.

14. The semiconductor package of claim 9, wherein the plurality of semiconductor chips includes at least one of a logic chip and a memory chip.

15. A semiconductor package comprising:
a package substrate;
an organic interposer above the package substrate and electrically connected to the package substrate through a first internal connection terminal,
the organic interposer including an organic body, a plurality of post electrodes penetrating the organic body from a top of the organic body to a bottom of the organic body, a lower redistribution structure arranged below the organic body and electrically connected to the plurality of post electrodes, and an upper redistribution structure arranged above the organic body and electrically connected to the plurality of post electrodes,
an inductor in at least one of the lower redistribution structure and the upper redistribution structure, a capacitor embedded in the organic body, and a bridge chip embedded in the organic body,
the plurality of post electrodes including a plurality of first post electrodes electrically connected to the inductor and a plurality of second post electrodes electrically connected to the lower redistribution structure and the upper redistribution structure; and
a plurality of semiconductor chips above the organic interposer and electrically connected to the organic interposer through a second internal connection terminal,
wherein the plurality of semiconductor chips includes a power management semiconductor chip,
wherein the power management semiconductor chip is above and adjacent to the inductor and the capacitor,
wherein at least some of the plurality of semiconductor chips are electrically connected to each other by the bridge chip, and
wherein the plurality of semiconductor chips includes at least one of a logic chip and a memory chip.

16. The semiconductor package of claim 15, wherein the inductor includes a spiral redistribution pattern in at least one of the lower redistribution structure and the upper redistribution structure and the plurality of first post electrodes electrically connected to the spiral redistribution pattern.

17. The semiconductor package of claim 15, wherein one of the plurality of first post electrodes has a different diameter from another one of the plurality of first post electrodes.

18. The semiconductor package of claim 15, wherein the lower redistribution structure includes a lower redistribution pattern, the upper redistribution structure includes an upper redistribution pattern, and the plurality of second post electrodes is electrically connected to the lower redistribution pattern and the upper redistribution pattern.

19. The semiconductor package of claim 15, wherein the capacitor comprises a power management capacitor connected to the power management semiconductor chip.

20. The semiconductor package of claim 19, further comprising a chip capacitor inside the organic body and below the plurality of semiconductor chips, the chip capacitor being connected to the plurality of semiconductor chips.
